(19) United States
(12) Patent Application Publication
(10) Pub. No.: US 2015/0263274 A1
(43) Pub. Date: Sep. 17, 2015

(54) MAGNETIC FIELD APPLYING APPARATUS AND MANUFACTURING METHOD OF MAGNETIC MEMORY DEVICE

(71) Applicant: KABUSHIKI KAISHA TOSHIBA, Tokyo (JP)

(72) Inventors: Mikio MIYATA, Yokohama Kanagawa (JP); Kenji NOMA, Yokohama Kanagawa (JP); Shinya KOBAYASHI, Kawasaki Kanagawa (JP); Yosuke KOBAYASHI, Yokohama Kanagawa (JP); Masashi KAWAMURA, Kawasaki Kanagawa (JP); Nobuyuki OGATA, Odawara Kanagawa (JP)

(73) Assignee: KABUSHIKI KAISHA TOSHIBA, Tokyo (JP)

(21) Appl. No.: 14/481,427

(22) Filed: Sep. 9, 2014

Related U.S. Application Data
(60) Provisional application No. 61/951,978, filed on Mar. 12, 2014.

(51) Int. Cl. H01L 43/12; H01F 7/02; H01F 7/20

(52) U.S. Cl. CPC H01L 43/12; H01F 7/20; H01F 7/0273

(57) ABSTRACT

According to one embodiment, a magnetic field applying apparatus includes a stage on which a semiconductor wafer having a major surface provided with a magnetoresistive effect element is placed, and an external magnetic field supplying unit configured to supply an external magnetic field to the semiconductor wafer planed on the stage. The external magnetic field supplying unit is provided on a reverse surface side or a lateral surface side of the semiconductor wafer placed on the stage.

### CROSS-REFERENCE TO RELATED APPLICATIONS

This application claims the benefit of U.S. Provisional Application No. 61/951,978, filed Mar. 12, 2014, the entire contents of which are incorporated herein by reference.

### FIELD

Embodiments described herein relate generally to a magnetic field applying apparatus and a method of manufacturing a magnetic memory device.

### BACKGROUND

A magnetic memory device employing magnetoresistive effect elements has been proposed. In this device, information is stored based on the magnetization direction of a storage layer included in each magnetoresistive effect element. Therefore, it is considered important to estimate the magnetic characteristic.

### BRIEF DESCRIPTION OF THE DRAWINGS

FIG. 1 is a schematic view showing a magnetic field applying apparatus according to a first embodiment;

FIG. 2 is a schematic plan view of a semiconductor wafer structure according to the first embodiment;

FIG. 3 is a schematic plan view showing the structure of a magnetic field applying plate according to the first embodiment;

FIG. 4 is a schematic cross-sectional view showing the basic structure of a magnetoresistive effect element according to the first embodiment;

FIG. 4A is a cross-sectional view showing the basic structure of the magnetic memory device according to the first embodiment;

FIG. 4B is a circuit diagram showing the basic circuit structure of the magnetic memory device according to the first embodiment;

FIG. 5 is a schematic view showing a magnetic field applying apparatus according to a first modification of the first embodiment;

FIG. 6 is a schematic plan view showing a magnetic field applying plate according to the first modification of the first embodiment;

FIG. 7 is a schematic view showing a magnetic field applying apparatus according to a second modification of the first embodiment;

FIG. 8 is a schematic view showing a magnetic field applying apparatus according to a third modification of the first embodiment;

FIG. 9 is a flowchart illustrating a method of manufacturing a magnetic memory device according to a second embodiment;

FIG. 10 is a schematic view showing the structure of a magnetic memory device employed in a third embodiment;

FIG. 11 is a view showing a shift of magnetic hysteresis characteristic according to the third embodiment;

FIG. 12 is a view for explaining correction of the magnetic hysteresis characteristic according to the third embodiment;

FIG. 13 is a flowchart illustrating a method of manufacturing a magnetic memory device, according to the third embodiment;

FIG. 14 is a view showing a shift, from a reference value, of the magnetic hysteresis characteristic according to the third embodiment;

FIG. 15 is a view for explaining correction of the magnetic hysteresis characteristic according to the third embodiment;

FIG. 16 is a schematic view showing the entire structure of a measuring apparatus according to a fourth embodiment;

FIG. 17 is a schematic view showing a rough structure of a magnetic memory device according to the fourth embodiment;

FIG. 18 is a schematic view showing a detailed structure of the measuring apparatus according to the fourth embodiment;

FIG. 19 is a schematic view showing the planar positional relationship between the magnetic memory device and a magnetic shield according to the fourth embodiment; and

FIG. 20 is a flowchart showing a method of manufacturing the magnetic memory device of the fourth embodiment.

### DETAILED DESCRIPTION

In general, according to one embodiment, a magnetic field applying apparatus includes: a stage on which a semiconductor wafer having a major surface provided with a magnetoresistive effect element is placed; and an external magnetic field supplying unit configured to supply an external magnetic field to the semiconductor wafer planed on the stage. The external magnetic field supplying unit is provided on a reverse surface side or a lateral surface side of the semiconductor wafer placed on the stage.

Embodiments will be described with reference to the accompanying drawings.

### First Embodiment

FIG. 1 is a schematic view showing a magnetic field applying apparatus according to a first embodiment.

The magnetic field applying apparatus of the first embodiment comprises a stage 20 on which a semiconductor wafer 10 is placed, and an external magnetic field supplying unit 30 configured to supply an external magnetic field to the semiconductor wafer 10 on the stage 20. The semiconductor wafer 10 has a major surface (element-formed surface) provided with a magnetoresistive effect element, described later. The external magnetic field supplying unit 30 is provided on the reverse surface (non element-formed surface) side of the semiconductor wafer on the stage 20.

The external magnetic field supplying unit 30 comprises a magnetic field generating unit 31 configured to generate a magnetic field, and a magnetic field applying plate 32 interposed between the magnetic field generating unit 31 and the semiconductor wafer 10. The magnetic field generating unit 31 is provided in the stage 20. In the embodiment, the magnetic field generating unit 31 comprises a plurality of electomagnets. The intensity of the magnetic field generated by the magnetic field generating unit 31 can be changed by changing the amount of current flowing through the electromagnets. Further, the direction of the magnetic field generated by the magnetic field generating unit 31 can be changed by changing the direction of the current flowing through the electromagnets. In the first embodiment, the magnetic field applying plate 32 includes a single yoke 33. More specifically, the single yoke 33 is provided in a base formed of a nonmagnetic material. The yoke 33 is provided to increase the intensity of the magnetic field generated by the magnetic field generating unit 31, and is formed of, for example, NiFe. It should be noted that even when the magnetic field applying plate 32 is interposed between the semiconductor wafer 10 and the stage 20, the semiconductor wafer 10 can be held by, for example, vacuum suction.

FIG. 1 also shows a probe card 40. The probe card 40 is used to measure the characteristics of the elements formed on the semiconductor wafer 10, and comprises a plurality of probes 41. The probe card 40 is provided on the major surface (element-formed surface) side of the semiconductor wafer 10 to measure the element characteristics from the major surface side of the semiconductor wafer 10.

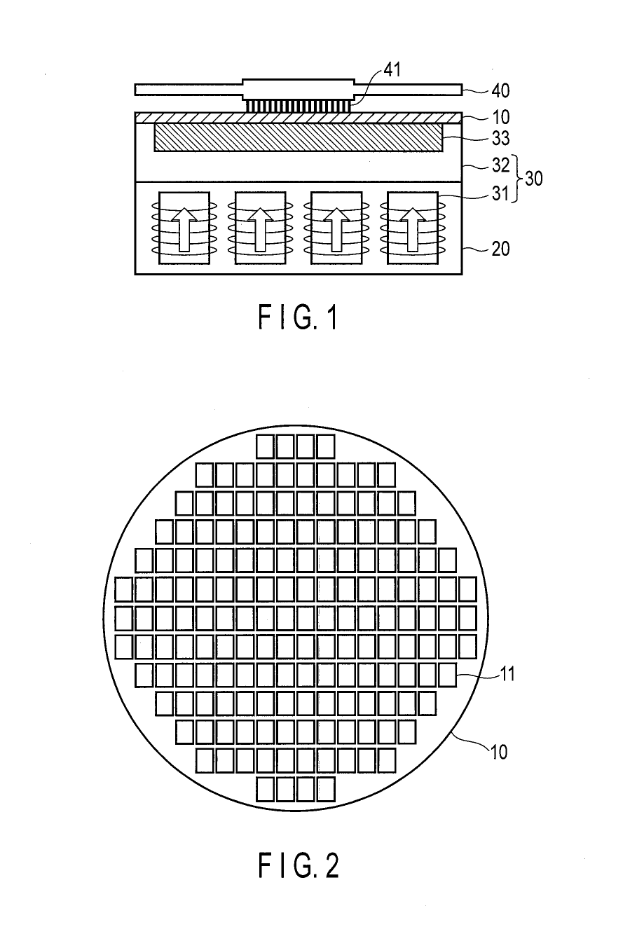

FIG. 2 is a schematic plan view showing the structure of the semiconductor wafer 10. A plurality of chip portions 11 are arranged in the semiconductor wafer 10. By dicing the semiconductor wafer in a later stage, a plurality of semiconductor chips are obtained.

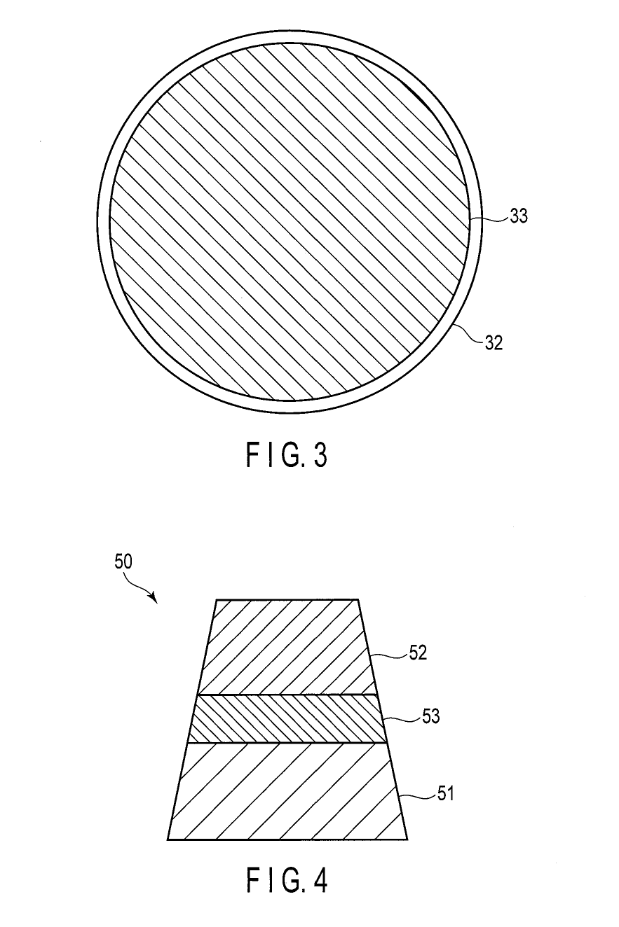

FIG. 3 is a schematic plan view showing the structure of the magnetic field applying plate 32. As shown in FIG. 3, the yoke 33 is provided on substantially the entire surface of the magnetic field applying plate 32 to completely cover the plurality of chip portions 11 in the semiconductor wafer 10.

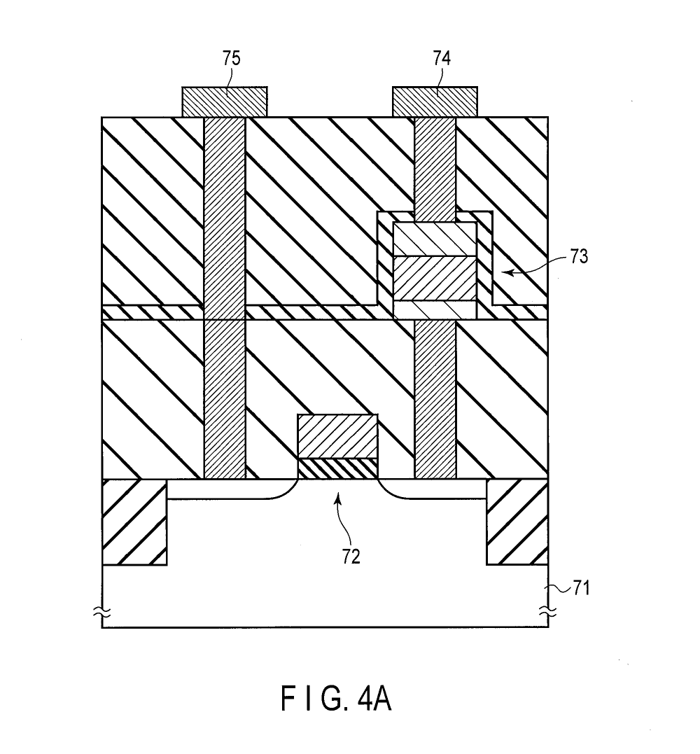

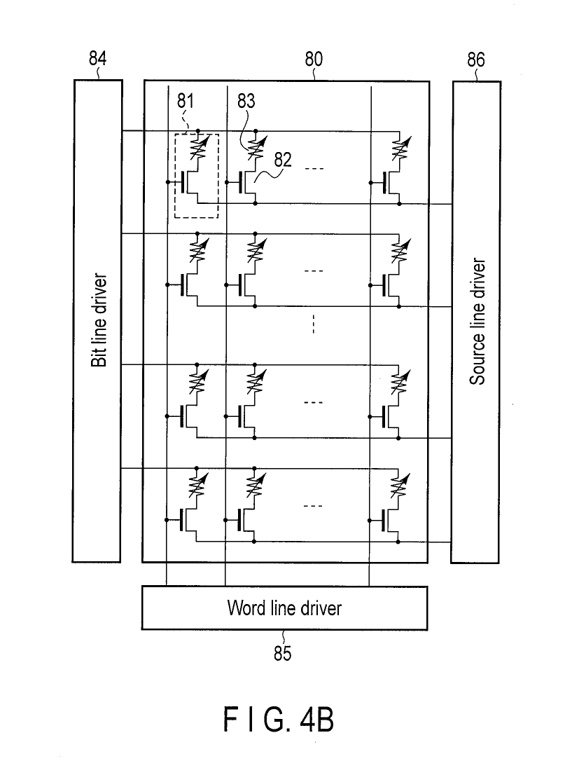

FIG. 4 is a schematic cross-sectional view showing the basic structure of a magnetoresistive effect element 50 provided on the semiconductor wafer 10.

The magnetoresistive effect element 50 of the first embodiment is of a spin transfer torque type having perpendicular magnetization. More specifically, the magnetoresistive effect element (MTJ (magnetic tunnel junction)) 50 comprises a storage layer (first magnetic layer) 51 having variable magnetization, a reference layer (second magnetic layer) 52 having fixed magnetization, and a tunnel barrier layer (nonmagnetic layer) 53 interposed between the storage layer 51 and the reference layer 52. Information (0 or 1) is stored depending upon whether the magnetization direction of the storage layer 51 and that of the reference layer 52 is parallel or antiparallel. These two states are generated in accordance with the direction of the current flowing through the magnetoresistive effect element 50.

FIG. 4A is a cross-sectional view schematically showing the basic structure of the magnetic memory device including the magnetoresistive effect element.

A select transistor 72 is provided on a semiconductor substrate 71, and a magnetoresistive effect element 73 is provided above the semiconductor substrate 71. One end of the magnetoresistive effect element 73 is connected to one of the source and drain of the select transistor 72, and the other end of the magnetoresistive effect element is connected to a first bit line 74. Further, the other of the source and drain of the select transistor 72 is connected to a second bit line 75.

FIG. 4B is a circuit diagram showing the basic circuit structure of the magnetic memory device including the magnetoresistive effect element.

In a cell array area 80, a plurality of unit memory cells 81 each including a select transistor 82 and a magnetoresistive effect element 83 are arranged in an array. Those of the unit memory cells 81 arranged in columns are connected to a bit line driver 84 via respective bit lines. Similarly, those of the unit memory cells 81 arranged in the columns are connected to a source line driver 86 via respective source lines. Further, those of the unit memory cells 81 arranged in rows are connected to a word line driver 85 via respective word lines.

Each chip portion 11 (see FIG. 2) of the semiconductor wafer 10 (see FIGS. 1 and 2) contains the magnetic memory device shown in FIGS. 4A and 4B.

As described above, the magnetoresistive effect element 50 magnetically stores information. Therefore, it is important to estimate the magnetic characteristic of the magnetoresistive effect element 50. In order to estimate the magnetic characteristic of the magnetoresistive effect element 50, it is important to apply an external magnetic field to the magnetoresistive effect element 50. However, the probe card 40 is provided on the major surface (element forming surface) side of the semiconductor wafer 10 as shown in FIG. 1. Accordingly, if a magnetic field is applied from its major surface side, it is difficult to efficiently apply the magnetic field to the magnetoresistive effect elements 50.

In the first embodiment, the external magnetic field supplying unit 30 is provided on the reverse surface side of the semiconductor wafer 10 placed on the stage 20. Therefore, even if the probe card 40 is provided on the major surface side of the semiconductor wafer 10, a magnetic field can be efficiently applied to the semiconductor wafer 10 from the reverse surface side of the semiconductor wafer 10 without being obstructed by the probe card 40. As a result, the magnetic characteristic of the magnetoresistive effect element 50 on the semiconductor wafer 10 can be precisely estimated.

Further, since the magnetic field applying plate 32 is provided between the magnetic field generating unit 31 and the semiconductor wafer 10, a magnetic field can be efficiently applied to the semiconductor wafer 10, whereby the magnetic characteristic of the magnetoresistive effect element 50 can be more precisely estimated.

Furthermore, since the magnetic field generating unit 31 is formed of a plurality of electromagnets, the intensity of the magnetic field can be varied per each electromagnet. This enables the external magnetic field supplied to the semiconductor wafer 10 by the external magnetic field supplying unit 30 to have an intensity distribution parallel to the major surface of the semiconductor wafer 10. The characteristics of the magnetoresistive effect element 50 may vary within the surface of the semiconductor wafer 10. For instance, the characteristics of the magnetoresistive effect element 50 may vary between the central portion and peripheral portion of the semiconductor wafer 10. In this case, by varying the magnetic field intensity of each electromagnet, the intensity distribution of the external magnetic field can be controlled, whereby an appropriate magnetic field can be applied to the magnetoresistive effect elements 50 on the entire surface of the semiconductor wafer 10.

When the magnetic field generating unit 31 is formed of electromagnets, it is preferable to keep the power supply for the electromagnets in the ON state. This is because when the power supply for the electromagnets is turned on, overshoot will occur in the magnetic force of the electromagnets, whereby the magnetic characteristic of the magnetoresistive effect element 50 may not correctly be estimated. Keeping the power supply for the electromagnets in the ON state can avoid this problem.

A first modification of the first embodiment will now be described. Since this modification is similar to the first embodiment in basic structure, the matters described in the embodiment will not be described.

Although the magnetic field applying plate 32 of the above-described embodiment includes a single yoke 33, the modification comprises a plurality of yokes 33.

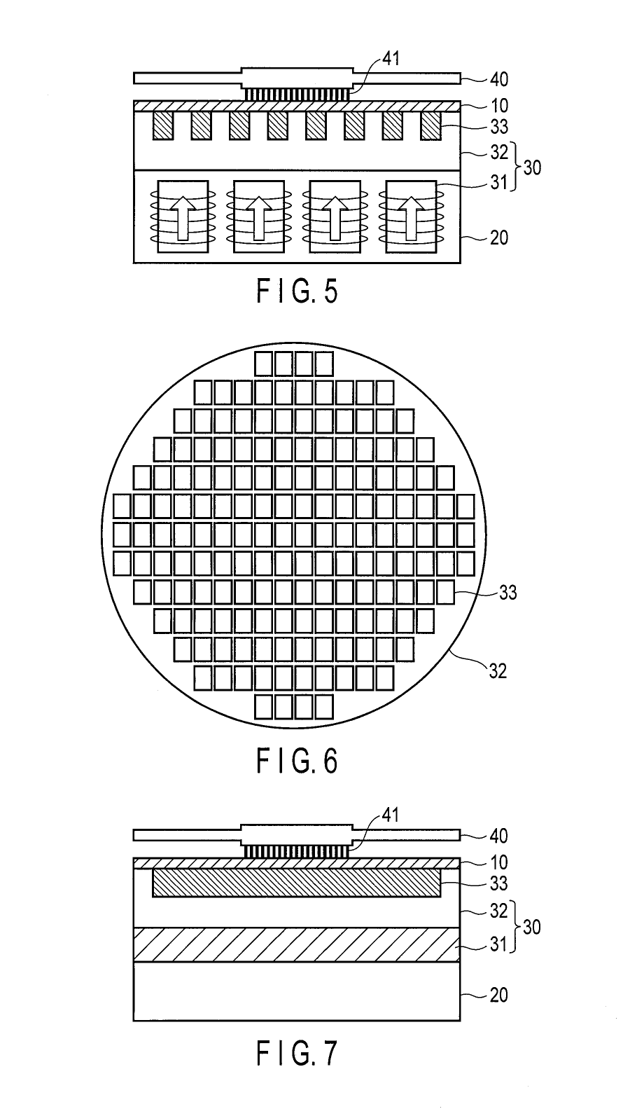

FIG. 5 is a schematic view showing a magnetic field applying apparatus according to the first modification. FIG. 6 is a schematic plan view showing the magnetic field applying plate 32 of the first modification.

As shown in FIGS. 5 and 6, a plurality of yokes 33 are provided on substantially the entire surface of the magnetic field applying plate 32. Further, as is evident from FIGS. 2 and 6, the plurality of yokes 33 are arranged at positions corresponding to a plurality of chip portions 11 in the semiconductor wafer 10. Namely, the positions of the yokes 33 are changed in accordance with the arrangement of the chip portions 11 that differs between products.

Thus, even when the magnetic field applying plate 32 has a plurality of yokes 33, the same basic advantage as that of the first embodiment can be obtained.

A second modification of the first embodiment will be described. Since this modification is similar to the first embodiment in basic structure, the matters described in the embodiment will not be described.

FIG. 7 is a schematic view showing a magnetic field applying apparatus according to the second modification. In the above-described embodiment, the magnetic field generating unit 31 is formed of electromagnets, while in the second modification, the magnetic field generating unit 31 is formed of permanent magnets.

Also in the case where the magnetic field generating unit 31 is formed of permanent magnets, the same basic advantage as in the above-described embodiment can be obtained. Further, the use of permanent magnets enables the apparatus size and cost to be reduced.

A third modification of the first embodiment will be described. Since this modification is similar to the first embodiment in basic structure, the matters described in the embodiment will not be described.

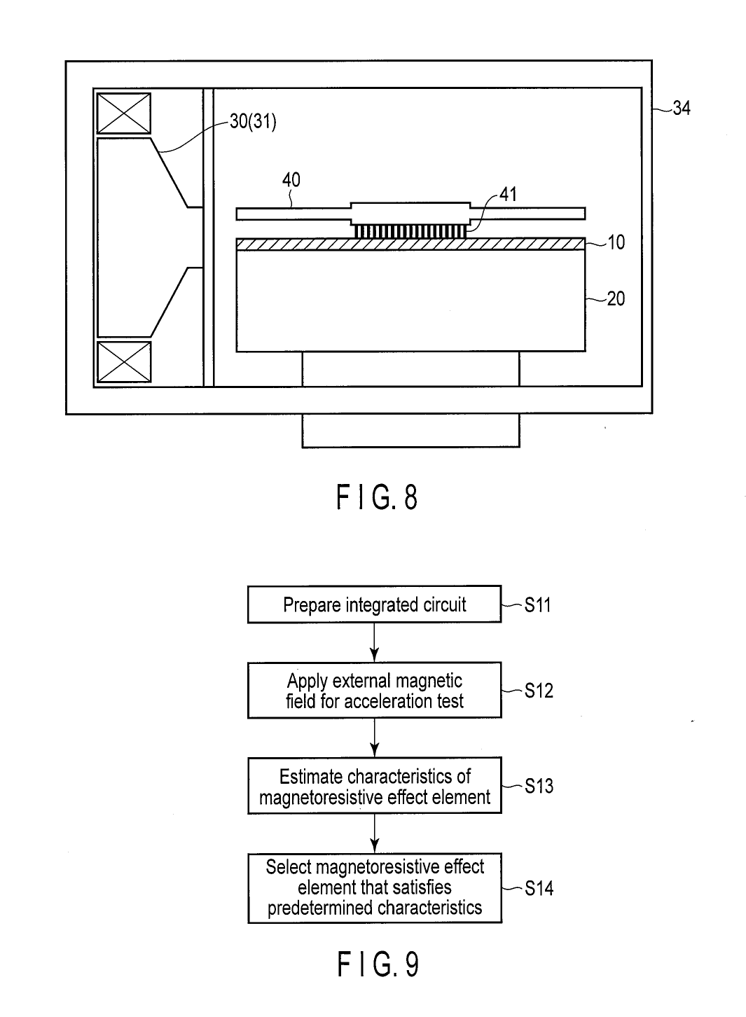

FIG. 8 is a schematic view showing a magnetic field applying apparatus according to the third modification. Although the above-described embodiment employs, as the magnetoresistive effect element, a spin transfer torque type element having perpendicular magnetization, the third modification employs, as the magnetoresistive effect element, a spin transfer torque type element having in-plane magnetization. Accordingly, in the third modification, the external magnetic field supplying unit 30 (magnetic field generating unit 31) is provided on the lateral surface side of the semiconductor wafer 10 placed on the stage 20. More specifically, electromagnets are used for the magnetic field generating unit 31, and the semiconductor wafer 10 is placed between the magnetic field generating unit 31 and a yoke 34.

Also in the case where an in-plane magnetization type element is used as the magnetoresistive effect element, the same basic advantage as that of the embodiment can be obtained by providing the external magnetic field supplying unit 30 on the lateral surface side of the semiconductor wafer 10.

### Second Embodiment

FIG. 9 is a flowchart illustrating a method of manufacturing a magnetic memory device according to the second embodiment.

Firstly, an integrated circuit including magnetoresistive effect elements, transistors, etc. is prepared on a semiconductor wafer (S11).

Subsequently, an external magnetic field for an acceleration test is applied to the semiconductor wafer with the integrated circuit formed thereon (S12).

Thus, an external magnetic field for an acceleration test is applied to the magnetoresistive effect elements formed on the semiconductor wafer. For this acceleration test, the magnetic field applying apparatus of the first embodiment can be used. More specifically, the acceleration test is performed as described below.

The semiconductor wafer 10 is placed on the stage shown in FIG. 1. Subsequently, an external magnetic field is supplied to the semiconductor wafer 10 by the external magnetic field supplying unit 30. The external magnetic field applied to the semiconductor wafer 10 is set greater than that applied to the semiconductor wafer in a normal state. When the external magnetic field is applied, a desired voltage, for example, may be applied by the probe card 40 to a desired portion of the semiconductor wafer 10. The external magnetic field is supplied to the semiconductor wafer 10 by the external magnetic field supplying unit 30 for a predetermined period. As a result of the application of the external magnetic field, the magnetic hysteresis characteristic of the magnetoresistive effect elements is shifted. By thus shifting the magnetic hysteresis characteristic, a magnetically accelerated state can be generated.

After thus applying the external magnetic field for the acceleration test to the magnetoresistive effect elements, the characteristics of the magnetoresistive effect elements are estimated using the probe card 40 (S13). The characteristics to be estimated include the data retention characteristic, read and write characteristics, etc., of the magnetoresistive effect elements.

After estimating the characteristics of each magnetoresistive effect element as described above, magnetoresistive effect elements that satisfy predetermined characteristics are selected (S14). Namely, selection is performed such that the magnetoresistive effect elements that satisfy predetermined characteristics are included in the circuit in each chip, whereas the magnetoresistive effect elements that do not satisfy the predetermined characteristics are excluded from the circuit in each chip.

Thereafter, dicing, packaging, etc., are performed, thereby completing the magnetic memory device.

As described above, in the second embodiment, appropriate estimation of the magnetic characteristics can be performed by applying an external magnetic field for the acceleration test to the magnetoresistive effect elements. As a result, magnetoresistive effect elements having appropriate characteristics can be accurately determined.

Although in the above-described embodiment, magnetoresistive effect elements that satisfy the predetermined characteristics are selected after the acceleration test is performed, element characteristics, such as element life duration, may be estimated from the estimation result of the acceleration test.

### Third Embodiment

A third embodiment will be described.

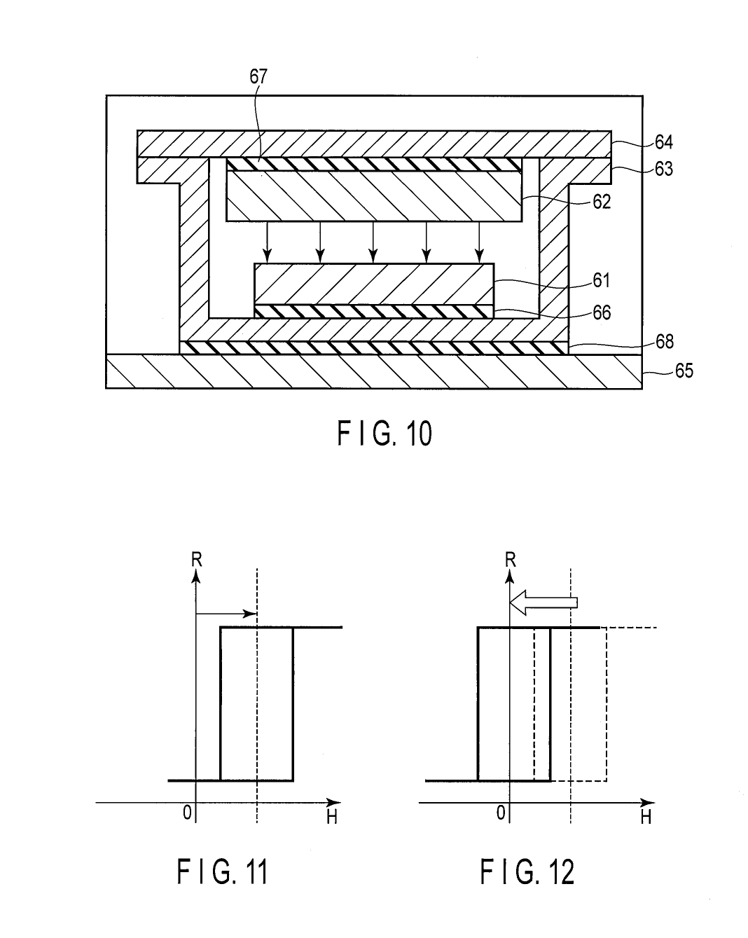

FIG. 10 is a schematic view showing the structure of a magnetic memory device used in a third embodiment.

The magnetic memory device used in the third embodiment comprises an integrated circuit chip 61 including a magnetoresistive effect element, a transistor, etc., and an internal magnetic field supplying unit 62 configured to supply a magnetic field to the magnetoresistive effect element. The basic structure of the magnetoresistive effect element is similar to that of the magnetoresistive effect element 50 shown in FIG. 4. The internal magnetic field supplying unit 62 is formed of a magnet for applying a shift correction magnetic field to the magnetoresistive effect element. More specifically, the internal magnetic field supplying unit 62 is configured to supply a magnetic field for reducing the magnetic field applied from the reference layer 52 to the storage layer 51 in the magnetoresistive effect element 50 shown in FIG. 4.

The integrated circuit chip 61 and the internal magnetic field supplying unit 62 are surrounded by magnetic shields 63 and 64. Further, the above-described structural elements are provided on a metal plate 65. The integrated circuit chip 61 and the magnetic shield 63 are connected by a Die Attach Film (DAF) 66. The internal magnetic field supplying unit 62 and the magnetic shield 64 are connected by a DAF 67. The magnetic shield 63 and the metal plate 65 are connected by a DAF 68. The metal plate 65 may be a lead frame formed by coupling a plurality of metal plates at the time of assemblage. Further, an insulating substrate may be used instead of the metal plate 65.

The function of the internal magnetic field supplying unit 62 will be described. In the magnetoresistive effect element 50 shown in FIG. 4, when a magnetic field is applied to the storage layer 51 by the reference layer 52, the magnetic hysteresis characteristic of the storage layer 51 is shifted as shown in FIG. 11. To correct this shift, the internal magnetic field supplying unit 62 is provided. Namely, when the internal magnetic field supplying unit 62 applies a magnetic field to the storage layer 51, the magnetic field applied by the reference layer 52 to the storage layer 51 is reduced.

However, the characteristics of the magnetoresistive effect element 50 differ between chips. Consequently, if a uniform magnetic field is supplied by the internal magnetic field supplying unit 62, it is difficult to perform appropriate correction. In light of this, the third embodiment employs the method described below to perform appropriate correction.

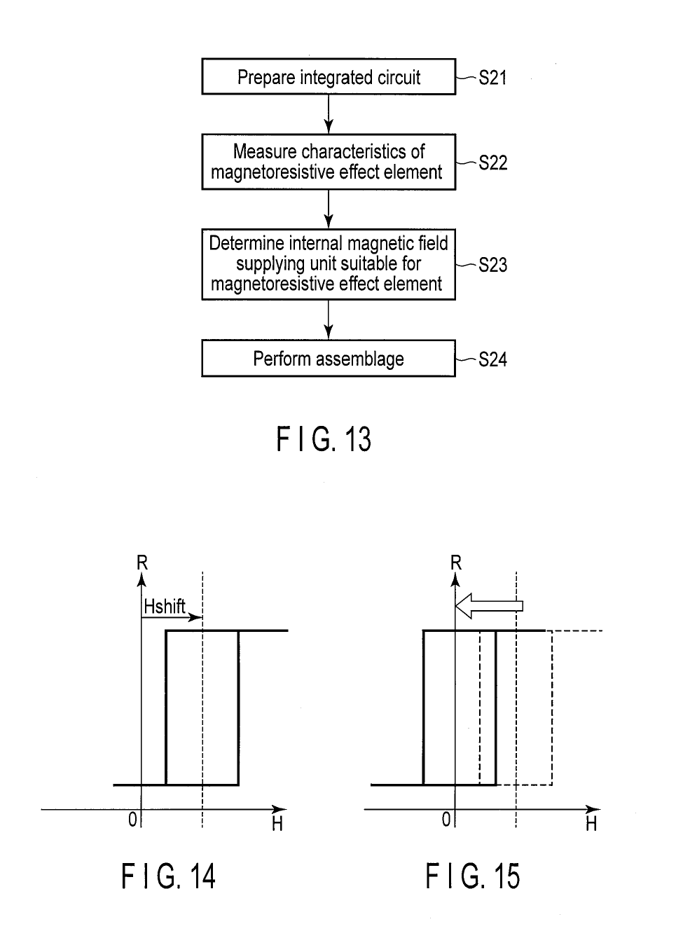

FIG. 13 is a flowchart illustrating a method of manufacturing a magnetic memory device, according to the third embodiment.

Firstly, an integrated circuit including magnetoresistive effect elements, transistors, etc. is formed on a semiconductor wafer (S21).

Subsequently, the characteristics of each magnetoresistive effect element are measured with an external magnetic field applied thereto (S22). The characteristics of each magnetoresistive effect element include the magnetic hysteresis characteristic. For the external magnetic field application, the magnetic field applying apparatus of the first embodiment can be used. The characteristics of each magnetoresistive effect element will be measured as follows:

Firstly, a semiconductor wafer is placed on the stage 20 shown in FIG. 1. Subsequently, an external magnetic field is supplied to the semiconductor wafer by the external magnetic field supplying unit 30. Namely, an external magnetic field is applied to the magnetoresistive effect elements formed on the semiconductor wafer. By applying the external magnetic field, the magnetic hysteresis characteristic of each magnetoresistive effect element on the semiconductor wafer is shifted. With the external magnetic field thus applied, the characteristic is measured using the probe card 40. More specifically, as shown in FIG. 14, the shift (Hshift) of the magnetic hysteresis characteristic of each magnetoresistive effect element from a reference value is measured.

After that, based on the measured characteristic, an internal magnetic field supplying unit 62 suitable for the magnetoresistive effect elements is determined (S23). Namely, based on the shift “Hshift” of the magnetic hysteresis characteristic from the reference value, an internal magnetic field supplying unit 62 that generates a magnetic field appropriate for correcting the magnetic hysteresis characteristic of each magnetoresistive effect element is selected. By selecting an optimal internal magnetic field supplying unit 62, the magnetic hysteresis characteristic of each magnetoresistive effect element can be corrected as shown in FIG. 15. For instance, in accordance with shifts “Hshift” in the magnetic hysteresis characteristic from the reference value, n ranks are set, and each internal magnetic field supplying unit 62 is classified into one of the n ranks in accordance with the intensity of its magnetic field. After that, an internal magnetic field supplying unit 62 having a rank corresponding to the rank of the shift “Hshift” from the magnetic hysteresis characteristic reference value is set as the optimal internal magnetic field supplying unit 62.

Thereafter, such a magnetic memory device as shown in FIG. 10 is assembled, using the magnetoresistive effect elements and the internal magnetic field supplying unit 62 appropriate for the magnetoresistive effect elements (S24). Namely, assemblage is performed, using an integrated circuit chip including the magnetoresistive effect elements and the internal magnetic field supplying unit 62 appropriate for the magnetoresistive effect elements.

As described above, in the third embodiment, the characteristics of the magnetoresistive effect elements are measured with an external magnetic field applied thereto, and an internal magnetic field supplying unit 62 appropriate for the magnetoresistive effect elements is determined based on the measured characteristics. Accordingly, characteristic correction appropriate for the magnetoresistive effect elements can be performed.

### Fourth Embodiment

A fourth embodiment will be described.

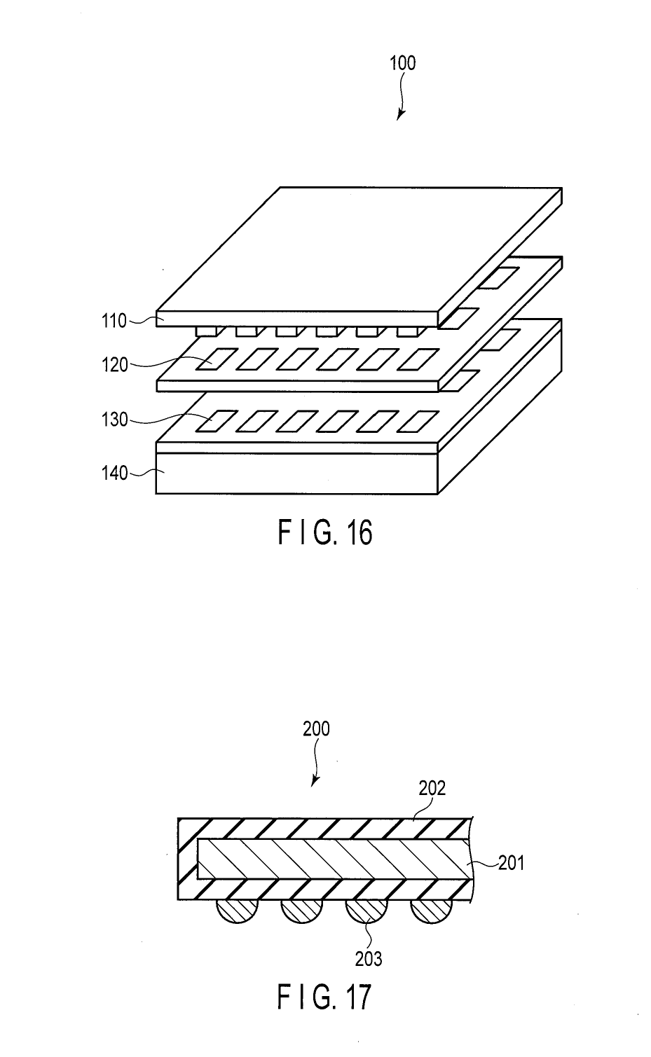

FIG. 16 is a view schematically showing the entire structure of a measuring apparatus according to the fourth embodiment.

As shown in FIG. 16, a measuring apparatus (testing device) 100 comprises a pusher 110, inserters 120, sockets 130 and a test unit 140. The measuring apparatus 100 is designed such that a plurality of magnetic memory devices as measuring targets can be set. Namely, during measurement, a plurality of magnetic memory devices as measuring targets are set in association with the corresponding inserters 120 and sockets 130.

FIG. 17 is a schematic view showing a rough structure of a magnetic memory device measured by the above-mentioned measuring apparatus 100.

As shown in FIG. 17, each magnetic memory device 200 comprises a semiconductor device chip 201 having a circuit including magnetoresistive effect elements, transistors, etc. (see FIGS. 4, 4A and 4B), a package 202 packaging the semiconductor device chip 201, and external terminals 203. Although in this embodiment, a ball grid array (BGA) package is used as the package 202, a thin small outline package (TSOP) or a package on package (POP) may be used instead.

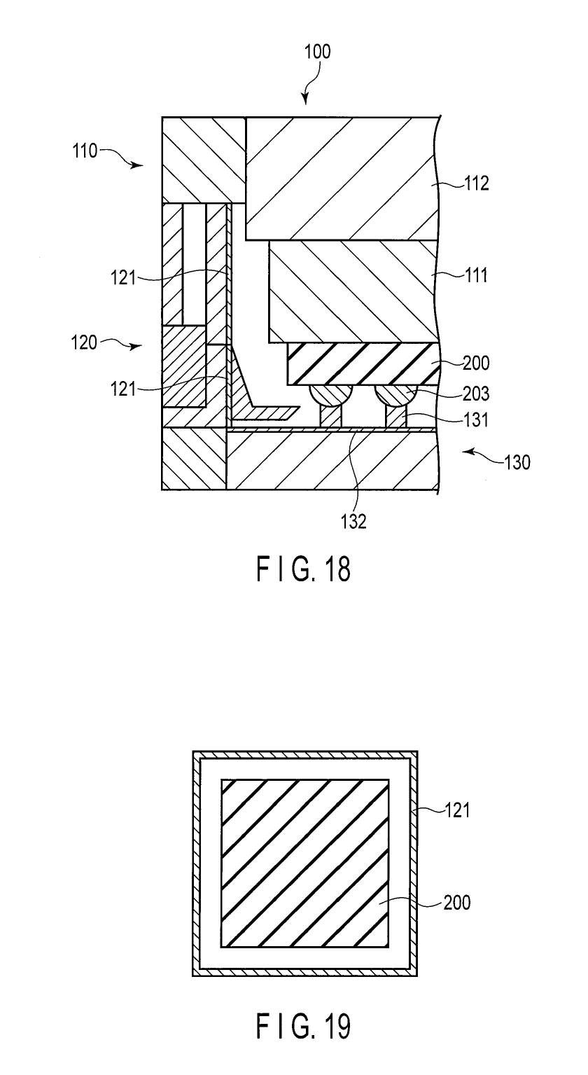

FIG. 18 shows part of the measuring apparatus of FIG. 16 in detail.

As shown in FIG. 18, when the characteristics of the magnetoresistive effect elements are measured, the magnetic memory devices 200 are inserted in the respective inserters 120, and the pusher 110 is pressed against the upper surfaces of the magnetic memory devices 200, whereby the magnetic memory devices 200 are connected to the sockets 130. More specifically, by pushing the pushing portions 111 of the pusher 110 against the upper surfaces of the magnetic memory devices 200, the terminals 203 of the magnetic memory devices 200 are connected to the terminals 131 of the sockets 130.

External magnetic field supplying units 112 are incorporated in the pusher 110. Each external magnetic field supplying unit 112 is formed of an electromagnet or a permanent magnet. When using an electromagnet as the material of each external magnetic field supplying unit 112, the direction and magnitude of the magnetic field can be changed by changing the direction and amount of the current flowing through the electromagnet. The external magnetic field supplying units 112 are provided for the respective magnetic memory devices 200. The pushing portions 111 are provided on the lower surfaces of the external magnetic field supplying units 112, and also serve as yokes. By virtue of this structure, external magnetic fields are applied by the external magnetic field supplying units 112 to the magnetoresistive effect elements included in the magnetic memory devices 200 set in the measuring apparatus 100.

The measuring apparatus 100 further comprises magnetic shields 121 configured to surround the respective magnetic memory devices 200 in measuring the characteristics of the magnetoresistive effect elements. More specifically, the magnetic shields 121 are provided on the inner surfaces of the respective inserters 120. The magnetic shields 121 can suppress influence of magnetism from adjacent external magnetic field supplying units 112.

FIG. 19 is a schematic view showing the planar positional relationship between each magnetic memory device 200 and the corresponding magnetic shield 121 according to the fourth embodiment. As shown in FIG. 19, each magnetic memory device 200 is surrounded by the corresponding magnetic shield 121.

Further, magnetic shields 132 are provided on the inner (upper) surfaces of the respective sockets 130. The magnetic shields 132 suppress the influence of magnetism upon the test unit 140 provided under the sockets 130.

The above-described measuring apparatus 100 is applicable to measurement of plural types of magnetic memory devices 200 having different specifications. Namely, by exchanging the pusher 110, inserters 120 and sockets 130 for other ones in accordance with the specifications (e.g., package specifications) of the magnetic memory devices 200, the measuring apparatus can measure plural types of magnetic memory devices 200 having different specifications.

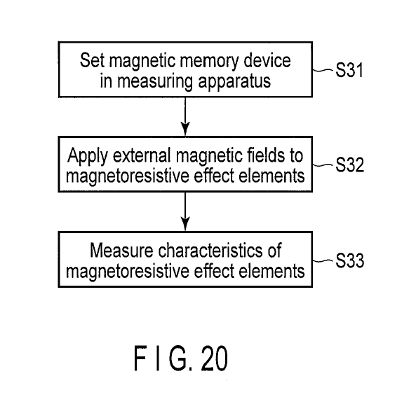

Referring then to the flowchart of FIG. 20, a description will be given of a method of manufacturing the magnetic memory device of the fourth embodiment.

Firstly, a plurality of magnetic memory devices 200 formed by packaging semiconductor device chips 201 including magnetoresistive effect elements are set in the measuring apparatus 100 including the external magnetic field supplying units 112 (S31). More specifically, in a state in which the magnetic memory devices 200 are set in the inserters 120, the pusher 110 is pressed against the upper surfaces of the magnetic memory devices 200. As a result, the magnetic memory devices 200 are connected to the corresponding sockets 130.

Note that the magnetoresistive effect elements are subjected to preliminary measurement before packaging the semiconductor device chips 201. Namely, the magnetoresistive effect elements are subjected to the measurement described above in each embodiment, before packaging the semiconductor device chips 201.

Subsequently, the external magnetic field supplying units 112 apply external magnetic fields to the magnetoresistive effect elements included in the respective magnetic memory devices 200 set in the measuring apparatus 100 (S32). Since the magnetic memory devices 200 are positioned under the external magnetic field supplying units 112 and the pushing portions (yokes) 111, external magnetic fields can be effectively applied to the magnetoresistive effect elements.

After that, the characteristics of the magnetoresistive effect elements are measured, with the external magnetic fields applied thereto (S33). In other words, where the magnetic memory devices 200 are set in the measuring apparatus 100, the test unit 140 measures the characteristics of the magnetoresistive effect elements. Specifically, measurements, such as write and read characteristics of the magnetoresistive effect elements, are performed. Since preliminary measurement is performed before packaging the semiconductor device chips 201, the measuring apparatus mainly performs measurements for discriminating defective products of the magnetic memory devices 200. Since thus, the characteristics of the magnetoresistive effect elements are measured with external magnetic fields applied thereto, discrimination of defective products can be effectively performed considering the influence of the external magnetic fields.

As described above, in the fourth embodiment, the magnetic memory devices 200 after packaging are set in the measuring apparatus to thereby measure the characteristics of the magnetoresistive effect elements with external magnetic fields applied thereto. This enables appropriate characteristic estimation of the magnetic memory devices 200 after packaging.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic field applying apparatus comprising:
a stage on which a semiconductor wafer having a major surface provided with a magnetoresistive effect element is placed; and
an external magnetic field supplying unit configured to supply an external magnetic field to the semiconductor wafer planed on the stage,
wherein the external magnetic field supplying unit is provided on a reverse surface side or a lateral surface side of the semiconductor wafer placed on the stage.

2. The apparatus of claim 1, wherein the external magnetic field supplying unit comprises:
a magnetic field generating unit configured to generate a magnetic field; and
a magnetic field applying plate provided between the magnetic field generating unit and the semiconductor wafer placed on the stage.

3. The apparatus of claim 2, wherein the magnetic field generating unit is provided within the stage.

4. The apparatus of claim 2, wherein the magnetic field applying plate includes a single yoke.

5. The apparatus of claim 2, wherein the magnetic field applying plate includes a plurality of yokes.

6. The apparatus of claim 5, wherein the plurality of yokes are arranged in accordance with an arrangement of a plurality of chip portions formed in the semiconductor wafer placed on the stage.

7. The apparatus of claim 1, wherein the external magnetic field supplied by the external magnetic field supplying unit has an intensity distribution in a direction parallel with the major surface of the semiconductor wafer.

8. The apparatus of claim 1, wherein the external magnetic field supplying unit includes an electromagnet.

9. The apparatus of claim 1, wherein the external magnetic field supplying unit includes a permanent magnet.

10. A method of manufacturing a magnetic memory device including a magnetoresistive effect element, comprising:
applying an external magnetic field to the magnetoresistive effect element; and
estimating characteristics of the magnetoresistive effect element after applying the external magnetic field to the magnetoresistive effect element.

11. The method of claim 10, wherein the external magnetic field is applied to the magnetoresistive effect element for an acceleration test.

12. The method of claim 10, wherein the characteristics of the magnetoresistive effect element includes a data retention characteristic of the magnetoresistive effect element.

13. The method of claim 10, wherein the characteristics of the magnetoresistive effect element includes a write characteristic of the magnetoresistive effect element.

14. The method of claim 10, wherein the characteristics of the magnetoresistive effect element includes a read characteristic of the magnetoresistive effect element.

15. The method of claim 10, further comprising selecting the magnetoresistive effect element satisfying a predetermined characteristic, after estimating the characteristics of the magnetoresistive effect element.

16. The method of claim 10, wherein
the external magnetic field is applied to the magnetoresistive effect element using a magnetic field applying apparatus, and
the magnetic field applying apparatus comprises:
a stage on which a semiconductor wafer having a major surface provided with the magnetoresistive effect element is placed; and
an external magnetic field supplying unit configured to supply the external magnetic field to the semiconductor wafer placed on the stage,
wherein the external magnetic field supplying unit is provided on a reverse surface side or a lateral surface side of the semiconductor wafer placed on the stage.

17. A method of manufacturing a magnetic memory device including a magnetoresistive effect element, and an internal magnetic field supplying unit configured to supply a magnetic field to the magnetoresistive effect element, the method comprising:
measuring characteristics of the magnetoresistive effect element with an external magnetic field applied to the magnetoresistive effect element; and
determining the internal magnetic field supplying unit suitable for the magnetoresistive effect element, based on the measured characteristics.

18. The method of claim 17, wherein the characteristics of the magnetoresistive effect element include a magnetic hysteresis characteristic.

19. The method of claim 17, wherein
the external magnetic field is applied to the magnetoresistive effect element using a magnetic field applying apparatus, and
the magnetic field applying apparatus comprises:
a stage on which a semiconductor wafer having a major surface provided with the magnetoresistive effect element is placed; and
an external magnetic field supplying unit configured to supply the external magnetic field to the semiconductor wafer planed on the stage,
wherein the external magnetic field supplying unit is provided on a reverse surface side or a lateral surface side of the semiconductor wafer placed on the stage.

20. A device set including a plurality of magnetic memory devices, wherein
each of the magnetic memory devices comprises a integrated circuit chip having a magnetoresistive effect element, and an internal magnetic field supplying unit configured to supply a magnetic field to the magnetoresistive effect element; and
magnetic fields of the internal magnetic field supplying units of at least two of the magnetic memory devices have different intensities.

21. The device set of claim 20, wherein the magnetic fields of the internal magnetic field supplying units of at least three of the magnetic memory devices have different intensities.

22. A method of manufacturing a magnetic memory device, comprising:
setting, in a measuring apparatus including an external magnetic field supplying unit, a magnetic memory device having a structure in which a semiconductor device chip including a magnetoresistive effect element is packaged;
applying an external magnetic field from the external magnetic field supplying unit to the magnetoresistive effect element included in the magnetic memory device set in the measuring apparatus; and
measuring a characteristic of the magnetoresistive effect element, with the external magnetic field applied to the magnetoresistive effect element.

23. The method of claim 22, wherein
the measuring apparatus includes a pusher which pushes an upper surface of the magnetic memory device when the characteristic of the magnetoresistive effect element is measured; and
the external magnetic field supplying unit is incorporated in the pusher.

24. The method of claim 22, wherein the measuring apparatus includes a magnetic shield which surrounds the magnetic memory device when the characteristic of the magnetoresistive effect element is measured.

25. The method of claim 22, wherein the external magnetic field supplying unit includes an electromagnet.

26. The method of claim 22, wherein the external magnetic field supplying unit includes a permanent magnet.

27. The method of claim 22, wherein a preliminary measurement is performed on the magnetoresistive effect element before the semiconductor device chip is packaged.
